(19) United States
(12) Patent Application Publication
(10) Pub. No.: US 2026/0339779 A1
(43) Pub. Date: Oct. 29, 2026

(54) MEMORY CONTROL METHOD AND STORAGE DEVICE

(71) Applicant: Hosin Global Electronics Co., LTD, Shenzhen (CN)

(72) Inventors: Chao-Yu Chen, Shenzhen (CN); Tsung-Lin Wu, Shenzhen (CN)

(73) Assignee: Hosin Global Electronics Co., LTD, Shenzhen (CN)

(21) Appl. No.: 19/660,029

(22) Filed: Apr. 27, 2026

(30) Foreign Application Priority Data
Apr. 29, 2025 (CN) 202510553963.2

(51) Int. Cl. G06F 11/10

(52) U.S. Cl. CPC G06F 11/1048; G06F 11/1068

(57) ABSTRACT

Disclosed are a memory control method and a storage device. The method includes: determining a first encoding rule according to a type of first data; encoding first sub-data in the first data according to the first encoding rule to generate a first error correction code corresponding to the first data without encoding second sub-data in the first data; storing the first data and the first error correction code to a first physical unit; reading second data and the first error correction code from the first physical unit; and correcting errors in the second data based on the first error correction code.

### CROSS-REFERENCE TO RELATED APPLICATION

This application claims the priority benefit of China application serial no. 202510553963.2, filed on Apr. 29, 2025. The entirety of the above-mentioned patent application is hereby incorporated by reference herein and made a part of this specification.

### BACKGROUND

### Technical Field

This disclosure relates to a field of memory control technology, and particularly relates to a memory control method and a storage device.

### Related Art

In solid-state storage devices (SSDs), due to the intrinsic characteristics of flash memory technology, data is prone to various categories of error during storage, particularly bit-flip errors, thereby necessitating that the SSD controller incorporate Error Correction Code (ECC) circuitry to ensure data integrity.

In solid-state drives (SSDs), ECC circuitry constitutes a critical component for detecting and correcting bit errors occurring within memory cells. By appending redundant information to the original data, ECC enables the SSD controller, upon reading, to detect and remedy a defined number of bit errors, thereby preserving data integrity and reliability. Notwithstanding that ECC may significantly enhance data reliability, its corrective capability is finite; that is, ECC may correct only up to a specified number of erroneous bits. In the event that the errors within a particular storage block exceed a maximum error rate tolerable under the ECC algorithm (commonly referred to as the “error correction capability” of an error correction code), the data in such block is unrecoverable notwithstanding the presence of ECC, resulting in irreversible data loss.

In view of the foregoing, the effective management of NAND flash has become one of the principal issues of concern for engineers within the industry.

### SUMMARY

This disclosure provides a memory control method and storage device that may improve the decode efficiency of the storage device.

An embodiment of the present disclosure provides a memory control method for a storage device, wherein the storage device includes a memory module, and the memory control method includes: obtaining first data; detecting a type of the first data; determining a first encoding rule corresponding to the first data according to the type; encoding first sub-data in the first data according to the first encoding rule to generate a first error correction code corresponding to the first data without encoding second sub-data in the first data; after obtaining the first error correction code, storing the first data and the first error correction code to at least one first physical unit in the memory module; after storing the first data and the first error correction code to the at least one first physical unit, reading second data and the first error correction code from the at least one first physical unit; and correcting errors in the second data based on the first error correction code.

An embodiment of the present disclosure further provides a storage device, which includes a connection interface, a memory module, and a memory controller. The connection interface is configured to connect to a host system. The memory controller is connected to the connection interface and the memory module. The memory controller is configured to: obtain the first data; detect a type of the first data; determine a first encoding rule corresponding to the first data according to the type; encode first sub-data in the first data according to the first encoding rule to generate a first error correction code corresponding to the first data without encoding second sub-data in the first data; after obtaining the first error correction code, store the first data and the first error correction code to at least one first physical unit in the memory module; after storing the first data and the first error correction code to the at least one first physical unit, read second data and the first error correction code from the at least one first physical unit; and correct errors in the second data based on the first error correction code.

Based on the above, after detecting the type of the first data, the first encoding rule corresponding to the first data may be determined. According to the first encoding rule, the first sub-data in the first data may be encoded to generate the first error correction code, and the first data and the first error correction code may be stored to the memory module. In particular, the second sub-data in the first data is not encoded. Subsequently, after reading the second data and the first error correction code from the first physical unit, errors in the second data may be corrected based on the first error correction code. In this way, the decode efficiency for one or more special types of data may be improved, and the data-read speed may be improved.

### BRIEF DESCRIPTION OF THE DRAWINGS

FIG. 1 is a schematic diagram of a data storage system according to an embodiment of the present disclosure.

FIG. 2 is a schematic diagram of a memory controller according to an embodiment of the present disclosure.

FIG. 3 is a schematic diagram of managing a memory module according to an embodiment of the present disclosure.

FIG. 4 is a schematic diagram of encoding first sub-data in first data to generate a first error correction code according to an embodiment of the present disclosure.

FIG. 5 is a schematic diagram of encoding first sub-data in first data to generate a first error correction code according to an embodiment of the present disclosure.

FIG. 6 is a schematic diagram of determining first sub-data from first data according to a data filter mask according to an embodiment of the present disclosure.

FIG. 7 is a schematic diagram of decoding second data based on a first error correction code according to an embodiment of the present disclosure.

FIG. 8 is a flowchart of a memory control method according to an embodiment of the present disclosure.

### DESCRIPTION OF THE EMBODIMENTS

Reference will now be made in detail to exemplary embodiments of the present disclosure, examples of which are illustrated in the accompanying drawings. Wherever possible, the same reference numerals will be used throughout the drawings and the description to refer to the same or like parts.

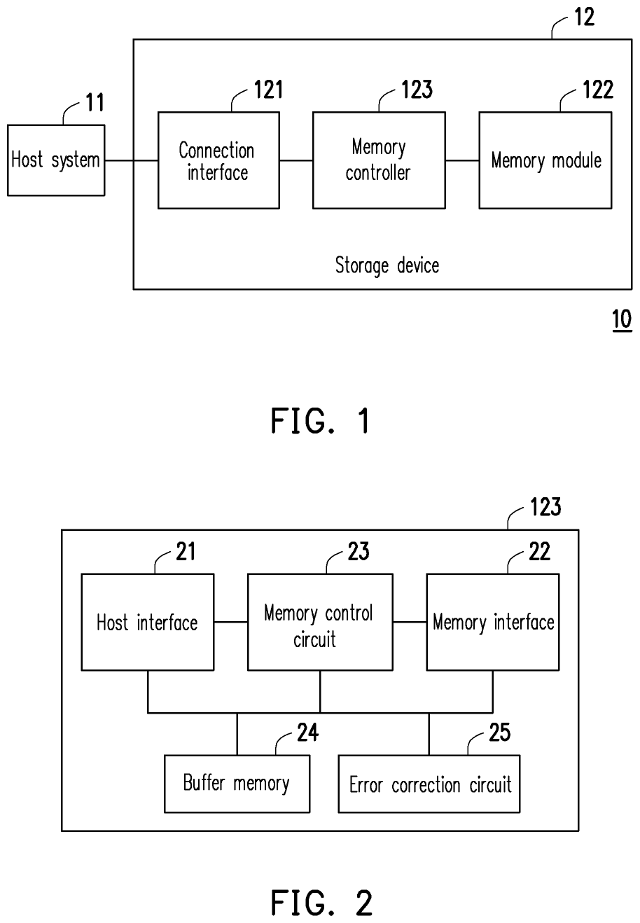

FIG. 1 is a schematic diagram of a data storage system according to an embodiment of the present disclosure. Referring to FIG. 1, a data storage system 10 includes a host system 11 and a storage device 12. The storage device 12 may be connected to the host system 11 and may be configured to store data from the host system 11. For example, the host system 11 may be a smartphone, a tablet computer, a notebook computer, a desktop computer, an industrial computer, a gaming console, a server, or a computer system installed in a specific carrier (such as a vehicle, aircraft, or ship), and the type of the host system 11 is not limited thereto. In addition, the storage device 12 may include a solid-state drive, a USB flash drive, a memory card, or other types of non-volatile storage devices.

The storage device 12 includes a connection interface 121, a memory module 122, and a memory controller 123. The connection interface 121 is configured to connect the storage device 12 to the host system 11. For example, the connection interface 121 may support embedded multimedia card (eMMC), universal flash storage (UFS), peripheral component interconnect express (PCI Express), non-volatile memory express (NVM express), serial advanced technology attachment (SATA), universal serial bus (USB), or other types of connection interface standards. Therefore, the storage device 12 may communicate with the host system 11 through the connection interface 121 (e.g., exchange signals, commands, and/or data).

The memory module 122 is configured to store data. For example, the memory module 122 may include one or more rewritable non-volatile memory modules. Each rewritable non-volatile memory module may include one or more memory cell arrays. The memory cells in the memory cell arrays store data in the form of voltages (also referred to as threshold voltages). For example, the memory module 122 may include single level cell (SLC) NAND flash memory modules, multi level cell (MLC) NAND flash memory modules, triple level cell (TLC) NAND flash memory modules, quad level cell (QLC) NAND flash memory modules, and/or other memory modules having the same or similar characteristics.

The memory controller 123 is connected to the connection interface 121 and the memory module 122. The memory controller 123 may be regarded as a control core of the storage device 12 and is configured to control the storage device 12. For example, the memory controller 123 may be configured to control or manage the overall or partial operation of the storage device 12. For example, the memory controller 123 may include a central processing unit (CPU), or other programmable general-purpose or special-purpose microprocessors, a digital signal processor (DSP), a programmable controller, an application specific integrated circuit(ASIC), a programmable logic device (PLD), or other similar devices or combinations of these devices. In an embodiment, the memory controller 123 may include a flash memory controller.

The memory controller 123 may send command sequences to the memory module 122 to access the memory module 122. For example, the memory controller 123 may send write command sequences to the memory module 122 to instruct the memory module 122 to store data in specific memory cells. For example, the memory controller 123 may send read command sequences to the memory module 122 to instruct the memory module 122 to read data from specific memory cells. For example, the memory controller 123 may send erase command sequences to the memory module 122 to instruct the memory module 122 to erase data stored in specific memory cells. In addition, the memory controller 123 may also send other types of command sequences to the memory module 122 to instruct the memory module 122 to execute other types of operations, which the present disclosure does not limit. The memory module 122 may receive command sequences from the memory controller 123 and access memory cells inside the memory module 122 according to the command sequences.

FIG. 2 is a schematic diagram of a memory controller according to an embodiment of the present disclosure. Please refer to FIG. 1 and FIG. 2, the memory controller 123 includes a host interface 21, a memory interface 22, and a memory control circuit 23. The host interface 21 is configured to connect to the host system 11 through the connection interface 121 to communicate with the host system 11. The memory interface 22 is configured to connect to the memory module 122 to access the memory module 122.

The memory control circuit 23 is connected to the host interface 21 and the memory interface 22. The memory control circuit 23 may be configured to control or manage the overall or partial operation of the memory controller 123. For example, the memory control circuit 23 may communicate with the host system 11 through the host interface 21 and access the memory module 122 through the memory interface 22. For example, the memory control circuit 23 may include control circuits such as embedded controllers or microcontrollers. In the following embodiments, the description of the memory control circuit 23 is equivalent to the description of the memory controller 123.

In an embodiment, the memory controller 123 may further include a buffer memory 24. The buffer memory 24 is connected to the memory control circuit 23 and is configured to buffer data. For example, the buffer memory 24 may be configured to buffer commands from the host system 11, data from the host system 11, and/or data from the memory module 122.

In an embodiment, the memory controller 123 may further include an error correction circuit 25. The error correction circuit 25 is connected to the memory control circuit 23 and is configured to perform encoding and decoding on data to ensure the correctness of the data. For example, the error correction circuit 25 may support various encoding/decoding algorithms such as low density parity check codes (LDPC code), BCH codes, Reed-solomon codes (RS code), Exclusive OR (XOR) codes, and the like. In an embodiment, the memory controller 123 may further include various other types of circuit modules (such as power management circuit, etc.), which are not limited by the present disclosure.

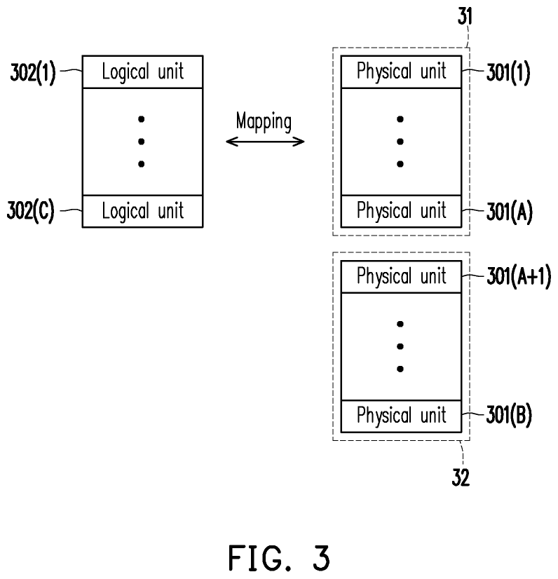

FIG. 3 is a schematic diagram illustrating management of a memory module according to an embodiment of the present disclosure. Referring to FIG. 1 to FIG. 3, the memory module 122 includes a plurality of physical units 301(1) to 301(B). Each physical unit includes a plurality of memory cells and is configured to non-volatilely store data.

In an embodiment, a physical unit may include a physical programmable unit. In an embodiment, a physical programmable unit may include a plurality of physical sectors. For example, the data capacity of a physical sector may be 512 bytes (B), and a physical programmable unit may include 32 physical sectors. However, the data capacity of a physical sector and/or the total number of physical sectors included in a physical programmable unit may be adjusted according to practical requirements, which are not limited by the present disclosure. In an embodiment, a physical programmable unit may be regarded as a physical page. For example, the storage capacity of a physical programmable unit may be 16 kilobytes, and the present disclosure is not limited thereto.

In an embodiment, a physical programmable unit is the minimum unit for synchronously writing data in the memory module 122. For example, when performing a programming operation (also referred to as a write operation) on a physical programmable unit to write data to this physical programmable unit, a plurality of memory cells in this physical programmable unit may be synchronously programmed to store corresponding data. For example, when programming a physical programmable unit, a write voltage may be applied to this physical programmable unit to change a threshold voltage of at least some memory cells in this physical programmable unit. For example, the threshold voltage of a memory cell may reflect the bit data stored by this memory cell.

In an embodiment, a physical erase unit may include a plurality of physical programmable units. The plurality of physical programmable units in a physical erase unit may be synchronously erased. For example, when performing an erase operation on a physical erase unit, an erase voltage may be applied to the plurality of physical programmable units in this physical erase unit to change a threshold voltage of at least some memory cells in these physical programmable units. By performing an erase operation on a physical erase unit, the data stored by this physical erase unit may be cleared. In an embodiment, a physical erase unit may be regarded as a physical block.

In an embodiment, the memory control circuit 23 may logically associate the physical units 301(1) to 301(A) and 301(A+1) to 301(B) to a data area 31 and a free area 32, respectively. All of the physical units 301(1) to 301(A) in the data area 31 store data (also referred to as user data) from the host system 11. For example, any physical unit in the data area 31 may store valid data and/or invalid data. In addition, none of the physical units 301(A+1) to 301(B) in the free area 32 stores data (e.g., valid data).

In an embodiment, if a specific physical unit does not store valid data, this physical unit may be associated to the free area 32. In addition, the physical units in the free area 32 may be erased to clear the data in these physical units. In an embodiment, the physical units in the free area 32 are also referred to as spare physical units. In an embodiment, the free area 32 is also referred to as a free pool.

In an embodiment, when data is to be stored, the memory control circuit 23 may select one or more physical units from the free area 32 and instruct the memory module 122 to store the data into the selected physical units. After storing the data into these physical units, these physical units may be associated to the data area 31. In other words, one or more physical units may be used alternately between the data area 31 and the free area 32.

In an embodiment, the memory control circuit 23 may configure a plurality of logical units 302(1) to 302(C) to be mapped to the physical units (i.e., physical units 301(1) to 301(A)) in the data area 31. For example, a logical unit may correspond to a logical block address (LBA) or other logical management units. A logical unit may be mapped to one or more physical units.

In an embodiment, if a specific physical unit is currently mapped by any logical unit, the memory control circuit 23 may determine that the data currently stored in this physical unit includes valid data. Conversely, if a specific physical unit is currently not mapped by any logical unit, the memory control circuit 23 may determine that this physical unit currently does not store any valid data.

In an embodiment, the memory control circuit 23 may record a mapping relationship between logical units and physical units in at least one management table (also referred to as a logical-to-physical mapping table). In an embodiment, the memory control circuit 23 may instruct the memory module 122 to execute operations such as data read, write, or erase according to the information in this management table (i.e., the logical-to-physical mapping table).

In an embodiment, the memory control circuit 23 may obtain data to be stored (also referred to as first data). The first data may generally refer to various data that is about to be stored in the memory module 122. For example, the first data may include data (e.g., user data) from the host system 11, program code (also referred to as firmware code) for operating the storage device 12, and/or data (also referred to as system data) for managing the storage device 12. User data refers to data that users want to save, such as documents, images, video files, etc. In addition, the program code for operating the storage device 12 may include firmware code. This firmware code may be stored in the memory controller 123 or the memory module 122.

In an embodiment, the system data includes one or more types of management data for a file system of the storage device 12. For example, the system data may include management data for various file systems such as FAT32, exFAT (Extended File Allocation Table), NTFS, ext4, F2FS (Flash-Friendly File System), YAFFS, APFS (Apple File System), Btrfs, or ZFS. The system data is crucial for managing and maintaining the file system and its structure of the storage device 12. Different types of storage devices 12 may use different file systems, and the internal data structures of different types of file systems may also differ.

FAT32 is the most commonly used file system for early USB flash drives. FAT32 has broad compatibility, and almost all operating systems may read and write USB flash drives in FAT32 format. However, FAT32 is subject to a limitation whereby any single file shall not exceed 4 GB in size. exFAT, developed by Microsoft for the purpose of remedying the limitations inherent in FAT32-particularly with respect to support for large files-supports substantially larger files and enjoys robust support in both Windows and macOS, and has gradually become the prevailing standard for USB flash drives. NTFS is primarily utilized by the Windows operating system; although some USB flash drives may employ NTFS, its cross-platform compatibility is inferior to that of FAT32 or exFAT. ext4 is commonly deployed on eMMC storage in Android devices. As a journaling file system, ext4 affords enhanced data integrity and recovery capabilities and is widely adopted in Linux systems. F2FS is a file system optimized for flash memory, primarily used in Android devices to improve performance and extend the service life of flash storage. YAFFS was formerly used as a file system in embedded systems, particularly on Android devices operating on earlier kernel versions. Btrfs is an advanced file system designed for Linux that supports copying, snapshots, checksumming, and other functionalities; although Btrfs remains under ongoing development, Btrfs has been adopted in some scenarios. ZFS is another advanced file system, originally developed by Sun Microsystems and now found across numerous systems; ZFS provides data redundancy, compression, snapshots, and related features, rendering ZFS well suited to data center environments.

Specifically, the circumstances under which the aforementioned products share some file systems are set forth below:

FAT32 and exFAT: By virtue of their broad compatibility, these two file systems are customarily employed across various categories of removable storage devices, including, without limitation, USB flash drives and solid-state drives (when used as external drives). ext4: Although primarily utilized in connection with the Linux operating system, this file system is deployed on multiple forms of storage media, including, without limitation, eMMC, UFS, and SSDs, particularly in Android devices and Linux servers. F2FS: This file system is principally employed for eMMC and UFS storage in mobile devices, so as to accommodate the inherent characteristics and requirements of flash memory.

In an embodiment, the system data includes File Allocation Table (FAT) data. In the field of storage technology, FAT data constitutes a portion of the file system. When the FAT data is written to the memory module 122, the FAT data exhibits characteristics that are distinct from those of user data writes. These differences are manifested primarily in the characteristics of data distribution and in the requirements regarding the distribution of logical “1”s and “0” s.

FAT data constitutes structured metadata utilized to record the allocation status of files within a file system. Each FAT entry (an “Entry,” typically 16-bit or 32-bit) indicates the location of the next cluster of a given file, or designates whether such cluster is unallocated. Unallocated clusters are commonly denoted by a specific value (e.g., all “0” s), whereas clusters allocated to a file contain an address pointing to the next cluster in the chain. Such structured data generally exhibits a high degree of regularity; that is, the distribution of “1”s and “0”s within FAT data follows specific patterns. By way of example, entries corresponding to unallocated clusters consist entirely of “0”s, whereas entries that point to other clusters contain a mixture of “1”s and “0”s.

On the other hand, user data is typically unstructured and may take any form, including, without limitation, text, images, video, and the like. The distribution of user data is generally random. Furthermore, to mitigate the risk of bit-flip errors, user data is subjected to a randomization process prior to being written to the memory module 122. For example, a block of data exhibiting the most favorable randomization effect may be selected for writing into the memory module 122. Accordingly, within the user data, the state of each bit (“1” or “0”) exhibits no discernible regularity.

In an embodiment, with respect to first data having structured characteristics (i.e., predetermined bit values or bit sequences) (for example, without limitation, the aforementioned FAT data), prior to storing such first data into the memory module 122, the memory control circuit 23 refrains from encoding of a portion of the first data that exhibits the foregoing structured characteristics, without employing the error correction circuit 25. Likewise, after reading data having the foregoing structured characteristics (also referred to herein as second data) from the memory module 122, the memory control circuit 23 refrains from encoding of a portion of the second data that exhibits the foregoing structured characteristics, without employing the error correction circuit 25. That is, during data access operations, it is unnecessary to perform encoding and decoding on those portions of the data that exhibit the foregoing structured characteristics. Accordingly, the error-correcting capability of the error correction code for such portion(s) of the data may be reallocated, for example, to remedy potential errors in the remaining portion(s) of the same data that do not exhibit the foregoing structured characteristics.

In an embodiment, with respect to the FAT32 file system, by way of example, for a USB flash drive having a capacity of 8 GB, the method for calculating the maximum possible number of bytes occupied by the FAT data (i.e., the size of a single File Allocation Table) is as follows:

In a FAT32 file system, the size of the FAT data is determined by the total number of clusters and the size of each FAT entry. For FAT32, each FAT entry occupies 4 bytes (32 bits), by reason of FAT32 being able to manage larger disk space and a greater number of clusters.

For the purpose of determining the maximum data capacity under FAT on a USB flash drive with a capacity of 8 GB, it is assumed that FAT32 supports a maximum volume size of 2 TB. In FAT32, the cluster size typically ranges from 512 bytes to 32 KB, depending on the total size of the volume. For a USB flash drive with a capacity of 8 GB, a common cluster size is 4 KB (4,096 bytes). With respect to a USB flash drive with a capacity of 8 GB, assuming a cluster size of 4 KB (4,096 bytes), the number of clusters may be calculated as follows:

$$\frac{8 \times 1024 \times 1024 \times 1024}{4096} = {2}^{21} = 2097152$$

(i.e., 2,097,152 clusters)

Furthermore, for purposes of this calculation, assuming that each FAT entry occupies 4 bytes, the size of the FAT data may be calculated as follows:
2097152×4 (bytes)=8388608 bytes=8 MB

Furthermore, the maximum possible value (i.e., the size of a single FAT data) of the number of bytes occupied by the FAT data may be expressed in hexadecimal as follows:
2×1024×1024 clusters=0×0020000

Alternatively, the expression may be converted to binary representation as follows:
0000 0000 0010 0000 0000 0000 0000 0000

As set forth above, when a FAT data is represented in binary, the first 10 bits of such FAT data may be regarded as partial data exhibiting the aforementioned structured characteristic (i.e., 10 consecutive “0”s), whereas the remaining bits of such FAT data do not exhibit the aforementioned structured characteristic. However, other types of management data may possess their respective corresponding and/or different forms of structured characteristics, and the present disclosure is not limited thereto.

By way of example, in an exFAT file system, the management data having the aforementioned structured characteristic may include FAT data and Cluster Bitmap data. The FAT data is configured to track the allocation status of clusters. In addition, the Cluster Bitmap data is configured to record which clusters have been used and/or which clusters are free. Alternatively, in an ext4 file system, the management data having the aforementioned structured characteristic may include Block Bitmap data. The Block Bitmap data is configured to track whether blocks on the disk have been allocated. Alternatively, in an F2FS file system, the management data having the aforementioned structured characteristic may include management data for Node Segments and Data Segments, which is configured to manage the allocation of metadata and user data, thereby improving read/write efficiency and reducing fragmentation. Alternatively, in an XFS file system, the management data having the aforementioned structured characteristic may include Allocation Group data, which includes metadata such as space allocation data and provides a more flexible approach to managing and recovering file allocation information. Moreover, additional types of management data may likewise possess the foregoing or similar structured characteristics, the details of which are not set forth herein.

In an embodiment, upon acquisition of the first data, the memory control circuit 23 may detect a type of the first data. For example, the memory control circuit 23 may determine whether the type of the first data is data having the foregoing structured characteristics (e.g., one or more of the foregoing items of management data), or data lacking the foregoing structured characteristics (e.g., user data or firmware data).

In an embodiment, where the type of the first data is data having structured characteristics, the memory control circuit 23 may further determine to which of the foregoing one or more kinds of management data the type of the first data belongs. For example, the memory control circuit 23 may determine that the type of the first data is management data for various file systems, including, without limitation, FAT32, exFAT, NTFS, ext4, F2FS, YAFFS, APFS, Btrfs, or ZFS. Furthermore, the types of data having structured characteristics may be defined or expanded in accordance with practical requirements, and the present disclosure is not limited thereto.

In an embodiment, upon determining the type of the first data, and in accordance with the type of the first data, the memory control circuit 23 may determine an encoding rule (also referred to as a first encoding rule) corresponding to the first data. For example, if the type of the first data is data having the foregoing structured characteristics, the memory control circuit 23 may determine the first encoding rule as an encoding rule that supports dynamic adjustment of an encoding/decoding mechanism. Thereafter, for the first data having the foregoing structured characteristics, the memory control circuit 23 may, based on the first encoding rule, dynamically adjust the encoding/decoding mechanism corresponding to the first data. Details of the relevant operations will be set forth hereinafter.

However, if the type of the first data lacks the aforementioned structured characteristics, the memory control circuit 23 may determine the first encoding rule to be a conventional encoding rule. For example, for first data that lacks the aforementioned structured characteristics, the memory control circuit 23 may, based on the conventional encoding rule, instruct the error correction circuit 25 to perform conventional encoding/decoding operations on the first data. By way of example, such conventional encoding/decoding operations include the error correction circuit 25 encoding the first data in its entirety (i.e., all data constituting the first data) to obtain an error correction code corresponding to the first data. Thereafter, the error correction circuit 25 may correct errors in the first data based on the error correction code.

In other words, in an embodiment, if the type of first data is a specific type (also referred to as a first type), the memory control circuit 23 may determine a candidate encoding rule (also referred to as a first candidate encoding rule) to be the first encoding rule. Alternatively, if the type of the first data is another type (also referred to as a second type), the memory control circuit 23 may determine another candidate encoding rule (also referred to as a second candidate encoding rule) to be the first encoding rule. The first type is distinct from the second type, and the first candidate encoding rule is distinct from the second candidate encoding rule. In the following embodiments, the first encoding rule that supports dynamic adjustment of the encoding/decoding mechanism will be described in detail.

In an embodiment, upon determining the first coding rule, the memory control circuit 23 may, in accordance with the first coding rule and through the error correction circuit 25, encode a portion of the first data (hereinafter, the “first sub-data”) to generate an error correction code (hereinafter, the “first error correction code”) corresponding to the first data. However, the memory control circuit 23 and the error correction circuit 25 may refrain from encoding another portion of the first data (hereinafter, the “second sub-data”). Alternatively stated, the foregoing operation of generating the first error correction code involves encoding only the first sub-data within the first data, and does not involve encoding the second sub-data within the first data.

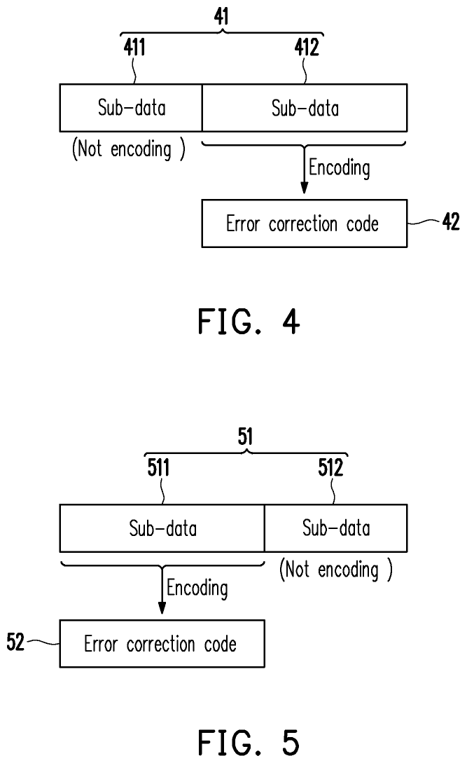

FIG. 4 is a schematic diagram showing encoding the first sub-data in the first data to generate the first error correction code according to an embodiment of the present disclosure. Please refer to FIG. 4, assuming that data 41 is the first data. The data 41 includes sub-data 411 (i.e., second sub-data) and sub-data 412 (i.e., first sub-data). According to the first encoding rule, the memory control circuit 23 may encode the sub-data 412 through the error correction circuit 25 to generate an error correction code 42 (i.e., the first error correction code). In particular, the generation of the error correction code 42 does not involve encoding the sub-data 411. It should be noted that the position or distribution of the first sub-data in the first data may be set or adjusted according to practical requirements, and the present disclosure is not limited thereto.

FIG. 5 is a schematic diagram showing encoding the first sub-data in the first data to generate the first error correction code according to an embodiment of the present disclosure. Please refer to FIG. 5, assuming that data 51 is the first data. The data 51 includes sub-data 511 (i.e., first sub-data) and sub-data 512 (i.e., second sub-data). According to the first encoding rule, the memory control circuit 23 may encode the sub-data 511 through the error correction circuit 25 to obtain an error correction code 52 (i.e., the first error correction code). In particular, the generation of the error correction code 52 does not involve encoding the sub-data 512. However, the position of the first sub-data in the first data may also be located at other positions in the first data, such as the middle section, rear section, etc. of the data of the first data, and the present disclosure is not limited thereto.

In an embodiment, after obtaining the first error correction code (such as error correction code 42 in FIG. 4 or error correction code 52 in FIG. 5), the memory control circuit 23 may store the first data (including the encoded first sub-data and the unencoded second sub-data) and the first error correction code to at least one physical unit (also referred to as a first physical unit) in the memory module 122.

Exemplarily, assuming that the first physical unit is at least one physical page (also referred to as the first physical page) in the memory module 122, the memory control circuit 23 may store the first data (including the encoded first sub-data and the unencoded second sub-data) to a data area (also referred to as a data bit area) in the first physical page, and store the first error correction code to a free area (also referred to as a redundant bit area) in the first physical page. That is, the first data (including the encoded first sub-data and the unencoded second sub-data) is stored in the data area (i.e., the data bit area) in the first physical page, while the first error correction code is stored in the free area (i.e., the redundant bit area) in the first physical page. At this point, the encoding and storing of the first data is completed.

In an embodiment, the memory control circuit 23 may store the first data (including the encoded first sub-data and the unencoded second sub-data) to the data area (also referred to as a data bit area) in the first physical page, store the first error correction code to a data area (also referred to as a data bit area) in a second physical page, and then, the memory control circuit 23 may encode the first error correction code through the error correction circuit 25 to generate a second error correction code, and store the second error correction code to a free area (also referred to as a redundant bit area) in the second physical page. Specifically, the encoding rule for the memory control circuit 23 to encode the first error correction code through the error correction circuit 25 to generate the second error correction code may optionally apply the first encoding rule and the second encoding rule in the context of the present disclosure, which will not be described in detail here.

In an embodiment, after determining the first encoding rule, according to the first encoding rule, the memory control circuit 23 may perform partial data extraction on the first data to obtain the first sub-data. Then, the memory control circuit 23 may encode the first sub-data through the error correction circuit 25 to generate the first error correction code.

In an embodiment, according to the first encoding rule, the memory control circuit 23 may further determine a mask (also referred to as a data filter mask). The data filter mask has a preset length corresponding to the first encoding rule. For example, a length (i.e., the preset length) of the data filter mask may be determined according to the first encoding rule. For example, when the first encoding rule changes, the determined length of the data filter mask may correspondingly change. According to the data filter mask, the memory control circuit 23 may determine the first sub-data from the first data. The preset length may be, for example, 1 KB, 2 KB, 4 KB, 8 KB, or 16 KB, which is not limited by the present disclosure.

In an embodiment, if the first encoding rule is a specific candidate encoding rule (e.g., a first candidate encoding rule), the memory control circuit 23 may determine a specific data filter mask (also referred to as a first data filter mask) as the data filter mask. Alternatively, if the first encoding rule is another candidate encoding rule (e.g., a second candidate encoding rule), the memory control circuit 23 may determine another data filter mask (also referred to as a second data filter mask) as the data filter mask. The first data filter mask may be different from the second data filter mask. For example, a length (also referred to as a first preset length) of the first data filter mask may be different from a length (also referred to as a second preset length) of the second data filter mask.

In an embodiment, after determining the data filter mask, the memory control circuit 23 may align the data filter mask with the first data according to an alignment rule. For example, the alignment rule may be determined according to the first encoding rule. For example, when the first encoding rule changes, the alignment rule may correspondingly change. For example, when the first encoding rule is a specific candidate encoding rule (e.g., a first candidate encoding rule), the memory control circuit 23 may determine a specific candidate alignment rule (also referred to as a first candidate alignment rule) as the alignment rule. Alternatively, when the first encoding rule is another candidate encoding rule (e.g., a second candidate encoding rule), the memory control circuit 23 may determine another candidate alignment rule (also referred to as a second candidate alignment rule) as the alignment rule. The first candidate alignment rule may be different from the second candidate alignment rule.

In an embodiment, after aligning the data filter mask with the first data, according to the length of the data filter mask, the memory control circuit 23 may extract at least one bit (also referred to as a first bit) from the first data as the first sub-data. In an embodiment, the first bit may refer to any bit in the first data that is located within an overlapping range of the data filter mask and the first data after aligning the data filter mask with the first data. Alternatively, in an embodiment, the first bit may also refer to any bit in the first data that is located outside the overlapping range of the data filter mask and the first data after aligning the data filter mask with the first data.

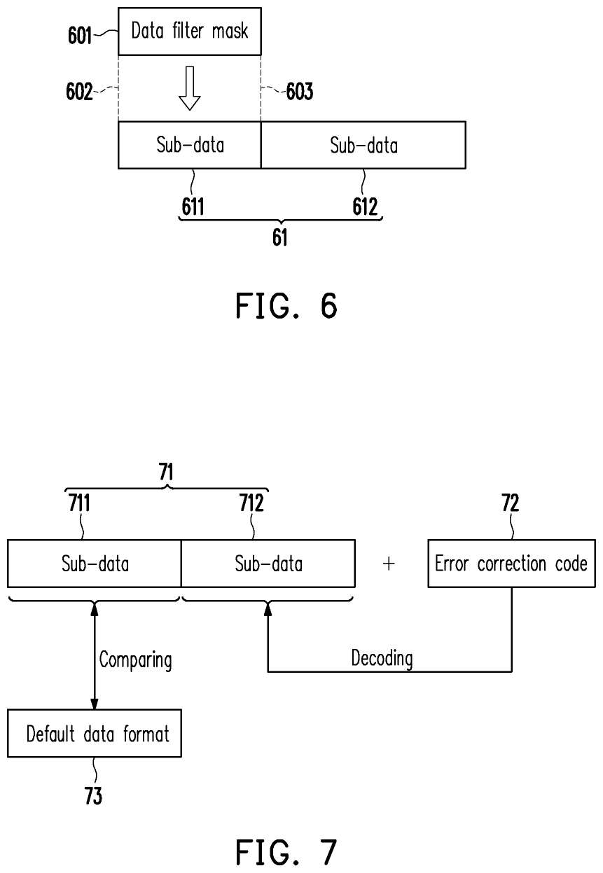

FIG. 6 is a schematic diagram showing determining first sub-data from the first data according to the data filter mask according to an embodiment of the present disclosure. Please refer to the figure, assuming that data 61 is the first data. According to a data filter mask 601, the memory control circuit 23 may determine sub-data 611 and sub-data 612 from the data 61.

In an embodiment, the memory control circuit 23 may determine the sub-data 611 as the first sub-data and determine the sub-data 612 as the second sub-data. Alternatively, in an embodiment, the memory control circuit 23 may determine the sub-data 612 as the first sub-data and determine the sub-data 611 as the second sub-data.

In an embodiment, assuming that the alignment rule adopted is aligning the data filter mask with the first bit of the first data. According to this alignment rule, the memory control circuit 23 may align the data filter mask 601 with the first bit of the data 61, as shown in FIG. 6. After aligning the data filter mask 601 with the data 61, the memory control circuit 23 may determine a threshold (also referred to as a first threshold) 602 and a threshold (also referred to as a second threshold) 603 according to an overlapping range of the data filter mask 601 and the data 61. The overlapping range of the data filter mask 601 and the data 61 is located between the threshold 602 and the threshold 603.

In an embodiment, the memory control circuit 23 may determine the data (i.e., sub-data 611) in the data 61 located between the threshold 602 and the threshold 603 as the first sub-data. For example, the memory control circuit 23 may extract each bit (i.e., first bit) from the sub-data 611 as the first sub-data. Meanwhile, the memory control circuit 23 may determine the data (i.e., sub-data 612) in the data 61 not located between the threshold 602 and the threshold 603 as the second sub-data. Thereafter, similar to the embodiment of FIG. 5, the sub-data 611 may be encoded to generate an error correction code (i.e., the first error correction code) corresponding to the data 61, and the sub-data 612 is not configured to generate the error correction code (i.e., the first error correction code) corresponding to the data 61.

Alternatively, in an embodiment, the memory control circuit 23 may determine the data (i.e., sub-data 612) in the data 61 not located between the threshold 602 and the threshold 603 as the first sub-data. For example, the memory control circuit 23 may extract each bit (i.e., first bit) from the sub-data 612 as the first sub-data. Meanwhile, the memory control circuit 23 may determine the data (i.e., sub-data 611) in the data 61 located between the threshold 602 and the threshold 603 as the second sub-data. Thereafter, similar to the embodiment of FIG. 4, the sub-data 612 may be encoded to generate the error correction code (i.e., the first error correction code) corresponding to the data 61, and the sub-data 611 is not configured to generate the error correction code (i.e., the first error correction code) corresponding to the data 61.

In an embodiment, the second sub-data in the first data includes at least one bit (also referred to as a second bit). The second bit is not involved in the aforementioned operation of encoding the first sub-data to generate the first error correction code. In particular, the second bit (or the second sub-data) has a default data format corresponding to the determined first encoding rule. For example, this default data format may be at least one bit “0” and/or at least one bit “1” arranged according to a preset arrangement rule. This default data format may be determined according to the first encoding rule. For example, when the first encoding rule changes, this default data format may correspondingly change. For example, when the first encoding rule is a specific candidate encoding rule (e.g., the first candidate encoding rule), the memory control circuit 23 may determine a specific candidate data format (also referred to as a first candidate data format) as this default data format. Alternatively, when the first encoding rule is another candidate encoding rule (e.g., the second candidate encoding rule), the memory control circuit 23 may determine another candidate data format (also referred to as a second candidate data format) as this default data format. The first candidate data format may be different from the second candidate data format.

In an embodiment, after storing the first data (including the encoded first sub-data and the unencoded second sub-data) and the first error correction code to the memory module 122 (e.g., the first physical unit), the memory control circuit 23 may read the first data and the first error correction code from the first physical unit. For example, the first data (including the encoded first sub-data and the unencoded second sub-data) may be read from a data area (i.e., data bit area) in the first physical page, while the first error correction code is read from a free area (i.e., redundant bit area) in the first physical page.

It should be noted that, to avoid confusion in terminology and description between the previously written first data and the subsequently read first data, in the following embodiments, the first data read from the first physical unit is renamed as second data. That is, the length of the second data and the storage location (i.e., the first physical unit) of the second data in the memory module 122 are respectively the same as the length of the first data and the storage location (i.e., the first physical unit) of the first data in the memory module 122. Furthermore, the data content difference between the first data and the second data may be regarded as being caused by read errors (or read faults) generated by performing data reading on the first physical unit. After obtaining the second data, the error correction circuit 25 may correct errors in the second data based on the first error correction code.

In an embodiment, after reading the second data and the first error correction code from the first physical unit, the memory control circuit 23 may query the encoding rule (also referred to as the second encoding rule) corresponding to the second data. For example, the second encoding rule is the same as the first encoding rule previously used when storing the first data.

In an embodiment, the memory control circuit 23 may uniformly record the encoding rules corresponding to at least part of the data in a management table. Subsequently, the memory control circuit 23 may query this management table to obtain the encoding rules (including the second encoding rule) corresponding to various data.

In an embodiment, after determining the second encoding rule (i.e., the aforementioned the first encoding rule), the memory control circuit 23 may determine part of the data (also referred to as third sub-data) from the second data according to this second encoding rule. For example, the distribution position of the third sub-data in the second data may be the same as the distribution position of the first sub-data in the first data. Then, the memory control circuit 23 may instruct the error correction circuit 25 to decode the third sub-data based on the first error correction code to correct errors in the third sub-data. However, it should be noted that this first error correction code will not be configured to decode the remaining data (also referred to as fourth sub-data) in the second data. For example, the distribution position of the fourth sub-data in the second data may be the same as the distribution position of the second sub-data in the first data.

In an embodiment, after determining the second encoding rule (i.e., the aforementioned the first encoding rule), according to the second encoding rule, the memory control circuit 23 may determine a default data format corresponding to the fourth sub-data. For example, the default data format corresponding to the fourth sub-data may be the same as the aforementioned default data format corresponding to the second sub-data. Then, without decoding the fourth sub-data based on the first error correction code, the memory control circuit 23 may correct errors in the fourth sub-data based on the determined default data format.

In an embodiment, if the second encoding rule is a specific candidate encoding rule (e.g., a first candidate encoding rule), the memory control circuit 23 may determine a specific candidate data format (e.g., a first candidate data format) as the default data format. Alternatively, if the second encoding rule is another candidate encoding rule (e.g., a second candidate encoding rule), the memory control circuit 23 may determine another candidate data format (e.g., a second candidate data format) as the default data format. For example, the distribution state of bits “0” and/or “1” reflected or presented by the first candidate data format may be different from the distribution state of bits “0” and/or “1” reflected or presented by the second candidate data format.

FIG. 7 is a schematic diagram of correcting second data based on the first error correction code according to an embodiment of the present disclosure. Please refer to FIG. 7, assuming that data 71 is the second data and an error correction code 72 is the first error correction code. The data 71 includes sub-data 711 and sub-data 712. The error correction code 72 may be regarded as being generated by encoding the sub-data 712. In addition, the generation of the error correction code 72 may be regarded as not involving encoding the sub-data 711.

In an embodiment, after obtaining the data 71 and the error correction code 72, the memory control circuit 23 may instruct the error correction circuit 25 to decode the sub-data 712 based on the error correction code 72 to correct errors in the sub-data 712. It should be noted that in the decode operation performed by the error correction circuit 25 on the sub-data 712 based on the error correction code 72, the error correction code 72 will not be configured to decode the sub-data 711.

On the other hand, after determining the encoding rule (i.e., the second encoding rule) corresponding to the data 71, the memory control circuit 23 may determine a default data format 73 corresponding to the sub-data 711 according to this encoding rule. After determining the default data format 73, the memory control circuit 23 may compare the bit distribution of the sub-data 711 with the default data format 73 to obtain a comparison result. This comparison result may present a difference between a bit distribution of the sub-data 711 and the default data format 73. In particular, this difference may be regarded as being caused by read errors (i.e., error bits) for the sub-data 711. Therefore, the memory control circuit 23 may correct errors in the sub-data 711 according to this comparison result. For example, according to this comparison result, the memory control circuit 23 may update the bit value distribution of all bits in the sub-data 711 to be consistent (i.e., the same) with the default data format 73.

It should be noted that, in contrast to a conventional decoding operation in which the error correction code is adopted to decode an entire data unit (e.g., data 71 in FIG. 7), in the embodiment of FIG. 7, the sub-data 712 is decoded based on the error correction code 72, and errors in the sub-data 711 are corrected by comparing the sub-data 711 with the default data format 73. This may increase the speed of error correction (or error detection) for the data 71, thereby accelerating the read speed of the data 71. In addition, by reducing the amount of data to be protected (or checked) by a single error correction code from the data 71 with a greater number of data to the sub-data 712 (or 711), the error-correction capability of the error correction circuit 25 may also be effectively enhanced.

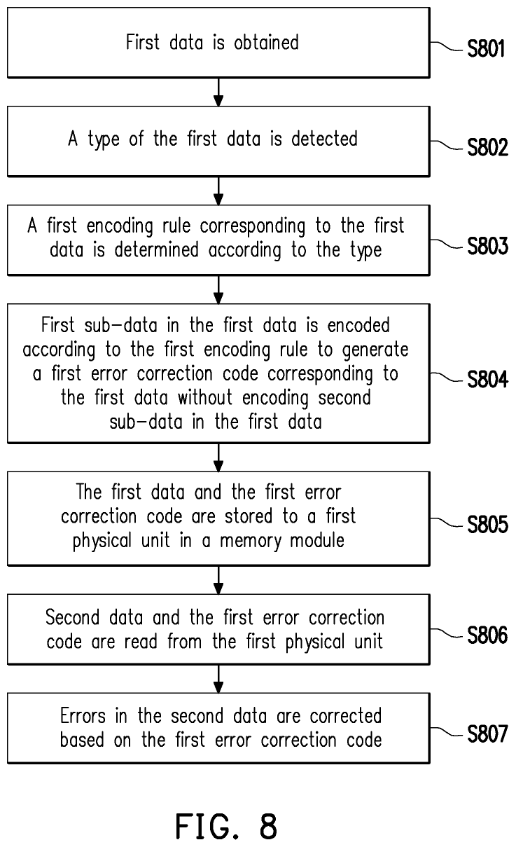

FIG. 8 is a flowchart of a memory control method according to an embodiment of the present disclosure. Referring to FIG. 8, in step S801, first data is obtained. In step S802, a type of the first data is detected. In step S803, a first encoding rule corresponding to the first data is determined according to the type. In step S804, first sub-data in the first data is encoded according to the first encoding rule to generate a first error correction code corresponding to the first data without encoding second sub-data in the first data. After obtaining the first error correction code, in step S805, the first data and the first error correction code are stored to at least one first physical unit in a memory module.

On the other hand, after storing the first data and the first error correction code to the memory module (i.e., the first physical unit), in step S806, second data and the first error correction code are read from the first physical unit. In step S807, errors in the second data are corrected based on the first error correction code.

However, the steps in FIG. 8 have been described in detail above, and thus will not be repeated here. It is worth noting that the steps in FIG. 8 may be implemented as multiple program codes or circuits, which is not limited by the present disclosure. In addition, the method of FIG. 8 may be used in conjunction with the above exemplary embodiments, or may be used independently, which is not limited by the present disclosure.

In summary, the memory control method and storage device proposed in the embodiments of the present disclosure may, without impairing (and even enhancing) the data protection capability (and/or error-correction capability) of the storage device, effectively increase data read speed for some specific types of data by substantially reducing the amount of data that must be decoded to perform error correction.

Finally, it should be noted that the above embodiments are only configured to illustrate the technical solutions of the present disclosure, rather than to limit them; although the present disclosure has been described in detail with reference to the aforementioned embodiments, those of ordinary skill in the art should understand that they may still modify the technical solutions described in the aforementioned embodiments, or make equivalent substitutions for some or all of the technical features therein; and these modifications or substitutions do not cause the essence of the corresponding technical solutions to depart from the scope of the technical solutions of the embodiments of the present disclosure.

What is claimed is:

1. A memory control method for a storage device comprising a memory module, and the memory control method comprises:
obtaining first data;
detecting a type of the first data;
determining a first encoding rule corresponding to the first data according to the type;
encoding first sub-data in the first data according to the first encoding rule to generate a first error correction code corresponding to the first data without encoding second sub-data in the first data;
after obtaining the first error correction code, storing the first data and the first error correction code to at least one first physical unit in the memory module;
after storing the first data and the first error correction code to the at least one first physical unit, reading second data and the first error correction code from the at least one first physical unit; and
correcting errors in the second data based on the first error correction code.

2. The memory control method according to claim 1, wherein the step of determining the first encoding rule corresponding to the first data according to the type comprises:
when the type is a first type, determining a first candidate encoding rule as the first encoding rule; and
when the type is a second type, determining a second candidate encoding rule as the first encoding rule.

3. The memory control method according to claim 1, wherein the step of performing the encoding on the first sub-data in the first data according to the first encoding rule comprises:
performing partial data extraction on the first data to obtain the first sub-data according to the first encoding rule.

4. The memory control method according to claim 3, wherein the step of performing the partial data extraction on the first data according to the first encoding rule to obtain the first sub-data comprises:
determining a data filter mask according to the first encoding rule; and
determining the first sub-data from the first data according to the data filter mask.

5. The memory control method according to claim 4, wherein the step of determining the data filter mask according to the first encoding rule comprises:
when the first encoding rule is a first candidate encoding rule, determining a first candidate data filter mask as the data filter mask; and
when the first encoding rule is a second candidate encoding rule, determining a second candidate data filter mask as the data filter mask.

6. The memory control method according to claim 4, wherein the step of determining the first sub-data from the first data according to the data filter mask comprises:
aligning the data filter mask with the first data according to an alignment rule; and
after aligning the data filter mask with the first data, extracting at least one first bit from the first data as the first sub-data according to a length of the data filter mask.

7. The memory control method according to claim 1, wherein the second sub-data comprises at least one second bit, and the at least one second bit has a default data format corresponding to the first encoding rule.

8. The memory control method according to claim 1, wherein the step of correcting the errors in the second data based on the first error correction code comprises:
determining a second encoding rule corresponding to the second data;
determining third sub-data from the second data according to the second encoding rule; and
decoding the third sub-data to correct errors in the third sub-data based on the first error correction code, and the first error correction code is not configured to decode fourth sub-data in the second data.

9. The memory control method according to claim 8, wherein the step of correcting the errors in the second data based on the first error correction code further comprises:
determining a default data format corresponding to the fourth sub-data according to the second encoding rule; and
correcting errors in the fourth sub-data based on the default data format.

10. The memory control method according to claim 9, wherein the step of determining the default data format corresponding to the fourth sub-data according to the second encoding rule comprises:
when the second encoding rule is a first candidate encoding rule, determining a first candidate data format as the default data format; and
when the second encoding rule is a second candidate encoding rule, determining a second candidate data format as the default data format.

11. A storage device, comprising:
a connection interface, configured to connect to a host system;
a memory module; and
a memory controller, connected to the connection interface and the memory module,
wherein the memory controller is configured to:
obtain first data;
detect a type of the first data;
determine a first encoding rule corresponding to the first data according to the type;
encode first sub-data in the first data according to the first encoding rule to generate a first error correction code corresponding to the first data without encoding second sub-data in the first data;
after obtaining the first error correction code, store the first data and the first error correction code to at least one first physical unit in the memory module;
after storing the first data and the first error correction code to the at least one first physical unit, read second data and the first error correction code from the at least one first physical unit; and
correct errors in the second data based on the first error correction code.

12. The storage device according to claim 11, wherein the operation of determining the first encoding rule corresponding to the first data according to the type comprises:
when the type is a first type, determining a first candidate encoding rule as the first encoding rule; and
when the type is a second type, determining a second candidate encoding rule as the first encoding rule.

13. The storage device according to claim 11, wherein the operation of performing the encoding on the first sub-data in the first data according to the first encoding rule comprises:
performing partial data extraction on the first data to obtain the first sub-data according to the first encoding rule.

14. The storage device according to claim 13, wherein the operation of performing the partial data extraction on the first data according to the first encoding rule to obtain the first sub-data comprises:
determining a data filter mask according to the first encoding rule; and
determining the first sub-data from the first data according to the data filter mask.

15. The storage device according to claim 14, wherein the operation of determining the data filter mask according to the first encoding rule comprises:
when the first encoding rule is a first candidate encoding rule, determining a first candidate data filter mask as the data filter mask; and
when the first encoding rule is a second candidate encoding rule, determining a second candidate data filter mask as the data filter mask.

16. The storage device according to claim 14, wherein the operation of determining the first sub-data from the first data according to the data filter mask comprises:
aligning the data filter mask with the first data according to an alignment rule; and
after aligning the data filter mask with the first data, extracting at least one first bit from the first data as the first sub-data according to a length of the data filter mask.

17. The storage device according to claim 11, wherein the second sub-data comprises at least one second bit, and the at least one second bit has a default data format corresponding to the first encoding rule.

18. The storage device according to claim 11, wherein the operation of correcting the errors in the second data based on the first error correction code comprises:
determining a second encoding rule corresponding to the second data;
determining third sub-data from the second data according to the second encoding rule; and
decoding the third sub-data to correct errors in the third sub-data based on the first error correction code, and the first error correction code is not configured to decode fourth sub-data in the second data.

19. The storage device according to claim 18, wherein the operation of correcting the errors in the second data based on the first error correction code further comprises:
determining a default data format corresponding to the fourth sub-data according to the second encoding rule; and
correcting errors in the fourth sub-data based on the default data format.

20. The storage device according to claim 19, wherein the operation of determining the default data format corresponding to the fourth sub-data according to the second encoding rule comprises:
when the second encoding rule is a first candidate encoding rule, determining a first candidate data format as the default data format; and
when the second encoding rule is a second candidate encoding rule, determining a second candidate data format as the default data format.
